(19) United States
(12) Patent Application Publication
(10) Pub. No.: US 2009/0102493 A1
(43) Pub. Date: Apr. 23, 2009

(54) Power Integrated Circuit with Bond-Wire Current Sense

(75) Inventors: Donald Ray Disney, Cupertino, CA (US); John S.K. So, Fremont, CA (US); David Yen Wai Wong, San Jose, CA (US)

Correspondence Address: ADVANCED ANALOGIC TECHNOLOGIES, 3230 Scott Blvd, Santa Clara, CA, 95054, US

(73) Assignee: ADVANCED ANALOGIC TECHNOLOGIES, INC., Sunnyvale, CA (US)

(21) Appl. No.: 11/874,744

(22) Filed: Oct. 18, 2007

(51) Int. Cl. G01R 31/26

(52) U.S. Cl. 324/719

(57) ABSTRACT

An integrated circuit product includes: 1) a package, 2) a semiconductor die mounted within the package, 3) a first terminal and a second terminal for connecting the integrated circuit product to an external circuit, 4) one or more bond wires for transferring a current received at the first terminal to the second terminal; and 5) a circuit included in the semiconductor die that measures a voltage difference attributable to the resistance of the bond wires to measure the magnitude of the current passing through the first terminal.

### BACKGROUND OF THE INVENTION

Power integrated circuits (PICs) are used in many applications. PICs typically combine control circuitry with one or more monolithically-integrated and/or co-packaged power transistors. Power transistors are capable of handling voltages and/or currents that are significantly higher than standard analog or digital integrated circuit devices. A common requirement in the design of PICs is to monitor the magnitude of peak or average current level that is flowing through one or more of the integrated power transistors and/or through an external load. It is important to implement this current sense function in a low-cost, compact manner and to minimize the tolerances in order to minimize the range of the current-limit specification.

In prior art implementations, current sensing has been accomplished using an external resistor to convert the current to a voltage, and one or more inputs to the PIC that monitor the voltage across the resistor. The main shortcomings of this approach are the addition of the external resistor, which adds size and cost to the solution, and the inability to trim out the variation in the resistor value, which necessitates the use of an expensive, high-precision resistor and/or increased tolerances on the current-sense specification. One representative prior-art solution is shown in FIG. 1. In this figure, PIC 11 has a main output terminal 12 through which the current to be sensed is flowing. A sense resistor 14 is placed in series with terminal 12 to convert the current to a voltage, and the voltage across resistor 14 is sensed by the PIC terminals 12 and 13. Inside the PIC, a sense amplifier or other current sense circuit is connected to terminals 12 and 13.

FIG. 2 shows another prior-art current sense solution including PIC 21. Main output terminal 22 is connected through inductor 25 to load 27. The inductor current is converted to a voltage by sense resistor 26. The voltage across resistor 26 is coupled to PIC 21 terminals 23 and 24, and a sense amplifier or other current sense circuit 28 inside PIC 21 is connected to terminals 23 and 24.

### SUMMARY OF THE INVENTION

An embodiment of the present invention includes a method for measuring a current by a semiconductor product. For a representative implementation, a semiconductor product includes a semiconductor die housed within a package. The package includes a series of terminals that are used to connect the semiconductor product to an external circuit. For the method being described, one of these terminals (a first terminal) is configured to receive (or sink) a current from the external circuit.

The first sense terminal is connected to a second terminal by a first set of one or more bond wires. This connection may be direct or, more typically pass through a pad located on semiconductor die. In this later type of configuration, one or more bond wires are attached between the first terminal and the pad and one or more bond wires are attached between the pad and the second terminal.

The semiconductor die includes a circuit that measures the voltage drop over the bond wires to determine the magnitude of the current received from the external circuit. Typically, this is done by amplifying the difference in voltage between the first terminal and the second terminal. It can also be done by comparing the difference in voltage between one of the terminals and the voltage present at the pad located on the semiconductor die. The amplified difference, along with a value that corresponds to the resistance of the bond wires is used to determine the magnitude of the current received from the external circuit. The resistance value is preferably programmable at the time of manufacture of the semiconductor product to account for variations in the bond wire resistance.

As a further refinement, the semiconductor die can be configured to generate a temperature correlated current and that current can be used to compensate for temperature dependent changes in the resistance of the bond wires.

For a second implementation, two semiconductor dies are included in a single package. The first die is a power device such as a MOSFET and the second is a more complex integrated circuit. A terminal in the package is connected by a set of one or more bond wires to source or sink an external current to or from the first semiconductor die. Additional bond wires transfer the voltage present at the terminal and the voltage at the connection of the set of bond wires to the first die to the second semiconductor die. Circuitry within the second semiconductor die uses these two voltages along with the resistance of the set of one or more bond wires to compute the magnitude of the current passing through the terminal.

### BRIEF DESCRIPTION OF THE DRAWINGS

FIG. 1 is a schematic diagram of a prior art PIC with external resistor current sense.

FIG. 2 is a schematic diagram of a prior art PIC with external resistor current sense.

FIG. 3 is a schematic diagram of an embodiment of the present invention with bond wire sense for an external current using two sense connections.

FIG. 4 is a schematic diagram of an embodiment of the present invention with bond wire sense for an external current using one sense connection.

FIG. 5 is a schematic diagram of an embodiment of the present invention with bond wire sense for an internal power device current using one sense connection.

FIG. 6 is a schematic diagram of an embodiment of the present invention with bond wire sense for a co-packaged power device current using two sense connections.

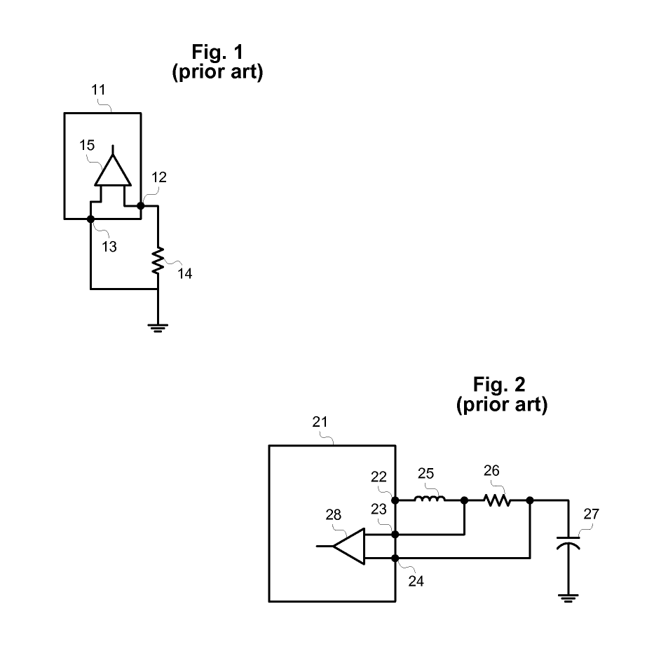

### DETAILED DESCRIPTION OF THE PREFERRED EMBODIMENTS

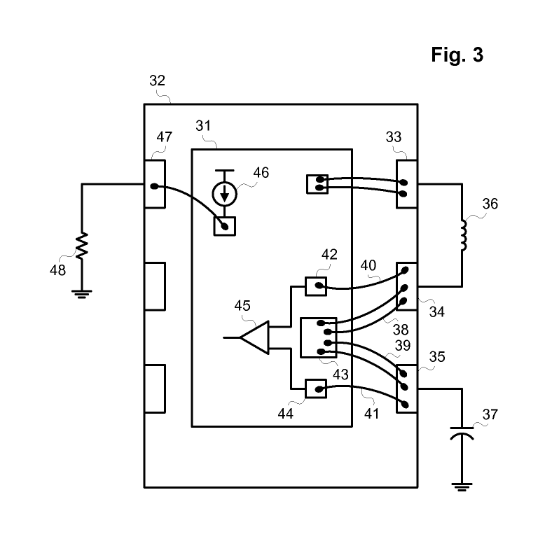

A first embodiment of the present invention is shown in FIG. 3. In FIG. 3, PIC 31 is housed inside package 32. Output terminal 33 comprises one or more leads on package 32 and is connected through inductor 36 to sense terminal 34, which comprises one or more leads on package 32. Sense terminal 34 is connected to common bond pad 43 via conventional IC assembly techniques, preferably one or more bond wires 38. Common bond pad 43 is also connected to sense terminal 35, in this example by one or more bond wires 39. Load 37 is connected to sense terminal 35. Current flow in this example is from output terminal 33 through inductor 36, bond wires 38, common pad 43, bond wires 39, to load 37. The inductor current is converted to a voltage drop by the resistance of bond wires 38 and 39, which comprise an integrated sense resistor. The voltage across this integrated sense resistor is coupled to a current sense circuit 45 inside PIC 31 via sense bond wires 40 and 41 connected between sense terminals 34 and 35 and sense bond pads 42 and 44.

The invention of FIG. 3 offers several advantages over the prior art solution of FIG. 2. By incorporating the current sense resistor into the PIC package, resistor 26 is eliminated, making the overall solution smaller and less expensive. Moreover, the internal bond-wire current sense can offer tighter tolerances than the external resistor. By incorporating a trimming technique after the PIC is packaged, variations in the wire bond resistance can be trimmed-out by adjusting the current sense circuit to account for variation inherent in the manufacturing of these bond wires. By way of example, the resistance of a gold bond wire may be expected to vary by up to +/−20% due to variation of bond wire diameter and length. Using post-package trimming with, for example, five trim bits, the current sense circuit can be adjusted to reduce the variation of the final current sense function to +/−2% or less. Such post-package trimming may be achieved, for example, by programming of on-chip EPROM cells, one-time programmable (OTP) cells, zener zapping, fuses, antifuses, or other well known techniques. In a preferred embodiment, post-package trim is provided by programming single-poly OTP memory cells using test-modes such that no additional pins are dedicated for the sole purpose of trimming.

In a preferred embodiment, the bond wires are made of aluminum, gold or their alloys. The diameter of the main bond wires 38 and 39 is chosen to accommodate the required current, and may be adjusted to set the desired total sense resistance. In a preferred embodiment gold wire with diameter in the range of 0.8 to 2.0 mils is used. Sense bond wires 40 and 41 are preferably the same diameter as the main bond wires, to minimize manufacturing cost. These sense bond wires ideally carry very little current, and therefore transfer the voltages from the sense terminals 34 and 35 to the sense circuit 45 with minimal perturbation.

To achieve a tighter tolerance of current sensing over a wide range of temperatures, the PIC preferably includes temperature compensation circuitry that is configured to compensate for the temperature coefficient of the bond wire material. Gold wire, for example, has a well known temperature coefficient of about 0.003715. FIG. 3 shows an internal current source 46 with a temperature coefficient given by I=Iref [1-0.003715(T-Tref)]. This current may be coupled to internal circuitry to generate the reference voltage, or it may preferably be coupled to external current set resistor 48 via ISET terminal 47, such that the absolute value of the current sense threshold may be set externally. In a preferred embodiment, the nominal value of current source 46 is in the range of 2 uA to 50 uA and the value of current set resistor 48 is in the range of 1 Okohm to 500 kohm. Because the temperature of the bond wire may be somewhat offset from the temperature of the PIC, it may also be preferable to adjust the temperature compensation circuitry to account for this difference. In one example, with 2 amps of current in the bond wire, the temperature difference between the wire and the PIC may be in the range of 5 to 15%.

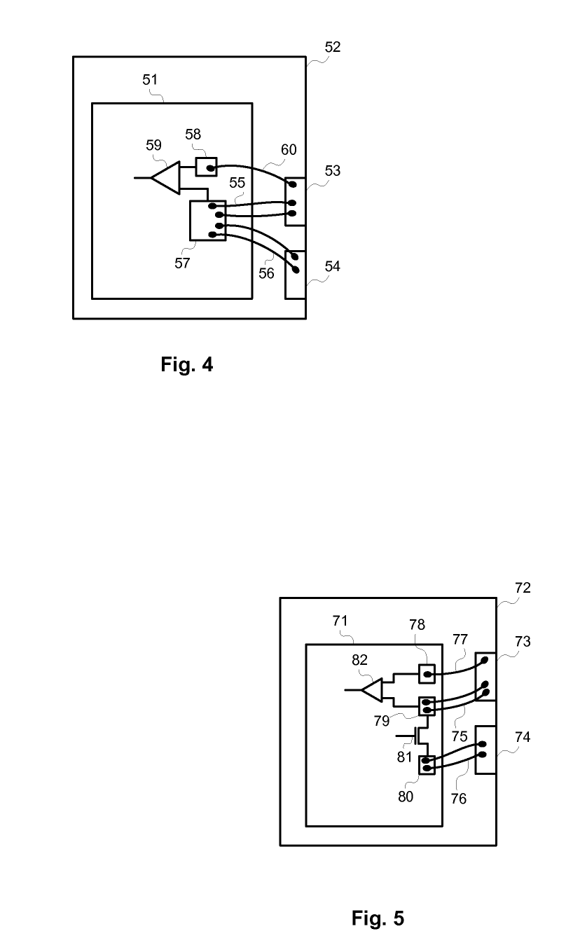

FIG. 4 shows another embodiment of the present invention, similar to that of FIG. 3 except that sense bond wire is used on only one side. PIC 51 is housed in package 52. Sense terminal 53 is connected to common bond pad 57 via one or more bond wires 55. Common bond pad 57 is also connected to sense terminal 54 by one or more bond wires 56. The current through bond wires 55 and 56 is converted to a voltage by the resistance of bond wires 55, which comprise an integrated sense resistor. The voltage across this integrated sense resistor is coupled to current sense circuit 59 inside PIC 51 via sense bond wire 60 and on-chip metallization from common bond pad 57. Compared to the FIG. 3 embodiment, the single sense bond example of FIG. 4 saves die area by eliminating one sense bond pad and saves package cost by eliminating one sense bond wire. However, the sense resistance is lowered by about half in this implementation, since bond wires 56 are not part of the integrated sense resistor. This may be advantageous for low current applications, in which fewer, smaller diameter wires are employed, while the FIG. 3 embodiment may be preferable for higher current applications with multiple, larger-diameter bond wires.

FIG. 5 shows another embodiment of the present invention. While FIGS. 3 and 4 showed the sensing of an external current that was routed through the PIC, the embodiment of FIG. 5 shows sensing of the current through an internal power device. PIC 71 is housed in package 72. Input terminal 73 is connected to power device 81 via one or more bond wires 75 and input bond pad 79. The other side of power device 81 is connected to output terminal 74 by output pad 80 and one or more bond wires 76. The current through power device 81 is converted to a voltage by the resistance of bond wires 75, which comprise an integrated sense resistor. The voltage across this integrated sense resistor is coupled to current sense circuit 82 inside PIC 71 via sense bond wire 77 and on-chip metallization from power device 81.

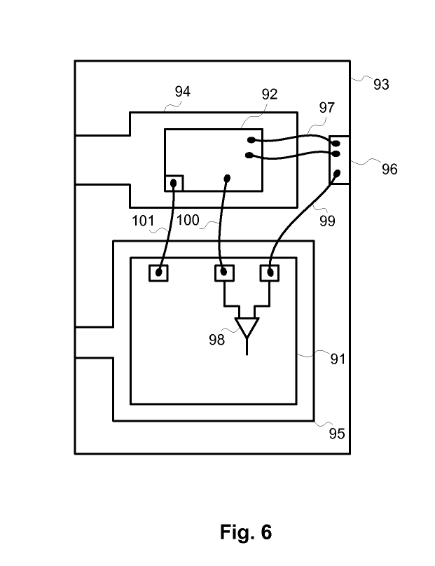

FIG. 6 shows another embodiment of the present invention, in which the current in a co-packaged power device is sensed. PIC 91 and discrete power device 92 are co-packaged in package 93, which in this example comprises a split lead frame. Power device 92 is mounted on lead frame portion 94 and PIC 91 is mounted on lead frame portion 95. In this example, the drain terminal of power device 92 is coupled to lead frame portion 94 and the source terminal of power device 92 is connected to terminal 96 by one or more bond wires 97. The current through power device 92 is converted to a voltage by the resistance of bond wires 97, which comprise an integrated sense resistor. The voltage across this integrated sense resistor is coupled to current sense circuit 98 inside PIC 91 via sense bond wire 99 from terminal 96 and sense bond wire 100 from the source terminal of power device 92. Also shown is gate bond wire 101 connecting the gate terminal of power device 92 to PIC 91.

What is claimed is:

1. In an integrated circuit product that includes a semiconductor die mounted within a package where the package includes at least a first terminal and a second terminal for connecting the integrated circuit product to an external circuit, a method for measuring the magnitude of a current used within the external circuit, the method comprising:
receiving the current at the first terminal;
transferring the current from the first terminal to the second terminal using one or more bond wires; and
measuring a voltage difference attributable to the resistance of the bond wires to measure the magnitude of the current used within the external circuit.

2. A method as recited in claim 1 that further comprises the step of comparing the voltage difference to a value that corresponds to the resistance of the one or more bond wires.

3. A method as recited in claim 2 in which the value is programmed during manufacture of the integrated circuit product to compensate for variations in the resistance of the one or more bond wires.

4. A method as recited in claim 1 that further comprises the steps of:
generating a current representative of the temperature of the semiconductor die; and
adjusting the measurement of the magnitude of the current based on the current representative of the temperature of the semiconductor die.

5. A method as recited in claim 1 in which the one or more bond wires includes a first set of one or more bond wires connecting the first terminal to a common pad on the semiconductor die and a second set of one or more bond wires connecting the common pad to the second terminal and where the step of measuring a voltage difference attributable to the resistance of the bond wires further comprises measuring the voltage difference between the first and second terminals.

6. A method as recited in claim 1 in which the one or more bond wires includes a first set of one or more bond wires connecting the first terminal to a common pad on the semiconductor die and a second set of one or more bond wires connecting the common pad to the second terminal and where the step of measuring a voltage difference attributable to the resistance of the bond wires further comprises measuring the voltage difference between the first terminal and the common pad.

7. A method as recited in claim 1 in which the one or more bond wires includes a first set of one or more bond wires connecting the first terminal to a first pad on the semiconductor die and a second set of one or more bond wires connecting the second terminal to a second pad on the semiconductor and where a circuit within the semiconductor die forms an electrical connection between the first and second pads where the step of measuring a voltage difference attributable to the resistance of the bond wires further comprises measuring the voltage difference between the first terminal and the first pad.

8. In an integrated circuit product that includes a first semiconductor die and a second semiconductor die mounted within a package where the package includes at least a first terminal for connecting the integrated circuit product to an external circuit, a method for measuring the magnitude of a current used within the external circuit, the method comprising:
receiving the current at the first terminal;
transferring the current from the first terminal to the first semiconductor die using one or more bond wires;
transferring the voltage of the first terminal (the first voltage) and the voltage of the current at the first semiconductor die (the second voltage) to the second semiconductor die; and
measuring the difference between the first and second voltages to measure the magnitude of the current used within the external circuit.

9. A method as recited in claim 8 that further comprises the step of comparing the voltage difference to a value that corresponds to the resistance of the one or more bond wires.

10. A method as recited in claim 9 in which the value is programmed during manufacture of the integrated circuit product to compensate for variations in the resistance of the one or more bond wires.

11. A method as recited in claim 8 that further comprises the steps of:
generating a current representative of the temperature of the semiconductor die; and
adjusting the measurement of the magnitude of the current based on the current representative of the temperature of the semiconductor die.

12. An integrated circuit product that includes:
a package
a semiconductor die mounted within the package;
a first terminal and a second terminal for connecting the integrated circuit product to an external circuit;
one or more bond wires for transferring a current received at the first terminal to the second terminal; and
a circuit included in the semiconductor die that measures a voltage difference attributable to the resistance of the bond wires to measure the magnitude of the current.

13. An integrated circuit product as recited in claim 12 in which the circuit included in the semiconductor die is configured to compare the voltage difference to a value that corresponds to the resistance of the one or more bond wires.

14. An integrated circuit product as recited in claim 13 in which the value is programmed during manufacture of the integrated circuit product to compensate for variations in the resistance of the one or more bond wires.

15. An integrated circuit product as recited in claim 12 in which the circuit included in the semiconductor die is configured to:
generate a current representative of the temperature of the semiconductor die; and
adjust the measurement of the magnitude of the current based on the current representative of the temperature of the semiconductor die.

16. An integrated circuit product as recited in claim 12 in which the one or more bond wires includes one or more bond wires connecting the first terminal to a common pad on the semiconductor die and one or more or more bond wires connecting the common pad to the second terminal and where the circuit included in the semiconductor die is configured to measure the voltage difference between the first and second terminals.

17. An integrated circuit product as recited in claim 12 in which the one or more bond wires includes one or more bond wires connecting the first terminal to a common pad on the semiconductor die and one or more or more bond wires connecting the common pad to the second terminal and where the circuit included in the semiconductor die is configured to measure the voltage difference between the first terminal and the common pad.

18. An integrated circuit product as recited in claim 12 in which the one or more bond wires includes one or more bond wires connecting the first terminal to a first pad on the semiconductor die and one or more or more bond wires connecting the second terminal to a second pad on the semiconductor and where a circuit within the semiconductor die forms an electrical connection between the first and second pads where the circuit included in the semiconductor die is configured to measure the voltage difference between the first terminal and the first pad.

19. An integrated circuit product that includes:
a package
a first semiconductor die mounted within the package;
a second semiconductor die mounted within the package;
a first terminal for connecting the integrated circuit product to an external circuit;
a first set of one or more bond wires for transferring a current received at the first terminal to the first semiconductor die; and
a circuit included in the second semiconductor die that measures a voltage difference attributable to the resistance of the first set of one or more bond wires to measure the magnitude of the current used within the external circuit.

20. An integrated circuit product as recited in claim 19 that further comprises:
a second set of one or more bond wires to transfer the voltage of the first terminal (the first voltage) to the second semiconductor die; and
a third set of one or more bond wires to transfer the voltage of the current at the first semiconductor die (the second voltage) to the second semiconductor die; and
the circuit measures the difference between the first and second voltages to measure the magnitude of the current.

21. An integrated circuit product as recited in claim 20 in which the circuit is configured to compare the voltage difference to a value that corresponds to the resistance of the first set of one or more bond wires.

22. An integrated circuit product as recited in claim 21 in which the value is programmed during manufacture of the integrated circuit product to compensate for variations in the resistance of the first set of one or more bond wires.

23. An integrated circuit product as recited in claim 20 in which the circuit included in the semiconductor die is configured to:
generate a current representative of the temperature of the second semiconductor die; and
adjust the measurement of the magnitude of the current based on the current representative of the temperature of the second semiconductor die.
